(19) United States
(12) Patent Application Publication
(10) Pub. No.: US 2024/0096912 A1
(43) Pub. Date: Mar. 21, 2024

(54) LIGHT RECEIVING DEVICE AND METHOD OF MANUFACTURING THE SAME

(71) Applicant: Sumitomo Electric Industries, Ltd., Osaka (JP)

(72) Inventor: Kazutoshi NATSUME, Osaka-shi (JP)

(73) Assignee: Sumitomo Electric Industries, Ltd., Osaka (JP)

(21) Appl. No.: 18/226,382

(22) Filed: Jul. 26, 2023

(30) Foreign Application Priority Data
Sep. 16, 2022 (JP) 2022-148252

(51) Int. Cl. H01L 27/146

(52) U.S. Cl. CPC H01L 27/14603; H01L 27/14649; H01L 27/14683

(57) ABSTRACT

A light receiving device includes a semiconductor layer, and at least one electrode provided on a surface of the semiconductor layer and electrically connected to the semiconductor layer. A plurality of mesas are formed from the semiconductor layer. The plurality of mesas are arranged in a two-dimensional array. The at least one electrode includes a plurality of electrodes, and each of the plurality of mesas is provided with a corresponding one of the plurality of electrodes. A contact portion has a periphery forming a closed curved shape, the contact portion being a portion at which the plurality of electrodes and the semiconductor layer are in contact with each other.

### CROSS REFERENCE TO RELATED APPLICATIONS

This application claims priority based on Japanese Patent Application No. 2022-148252, filed on Sep. 16, 2022, and the entire contents of the Japanese patent application are incorporated herein by reference.

### TECHNICAL FIELD

The present disclosure relates to a light receiving device and a method of manufacturing the same.

### BACKGROUND

In MIM capacitors, there is known a technique for alleviating electric field concentration in an electrode by changing the area of the electrode (for example, PTL 1). PTL 1: Japanese Unexamined Patent Application Publication No. 3-241864

### SUMMARY

A light receiving device according to the present disclosure includes a semiconductor layer, and at least one electrode provided on a surface of the semiconductor layer and electrically connected to the semiconductor layer. A plurality of mesas are formed from the semiconductor layer. The plurality of mesas are arranged in a two-dimensional array. The at least one electrode includes a plurality of electrodes, and each of the plurality of mesas is provided with a corresponding one of the plurality of electrodes. A contact portion has a periphery forming a closed curved shape, the contact portion being a portion at which the plurality of electrodes and the semiconductor layer are in contact with each other.

A method of manufacturing a light receiving device according to the present disclosure includes forming a plurality of mesas on a semiconductor layer, and forming an electrode on the plurality of mesas, the electrode being electrically connected to the semiconductor layer. The plurality of mesas are arranged in a two-dimensional array. The electrode is provided on a surface of the semiconductor layer. A periphery of a contact portion forms a closed curved shape, the contact portion being a portion at which the electrode and the semiconductor layer are in contact with each other.

### BRIEF DESCRIPTION OF THE DRAWINGS

FIG. 1 is a plan view illustrating a light receiving device according to a first embodiment.

FIG. 2A is an enlarged plan view of a mesa.

FIG. 2B is a cross-sectional view taken along line A-A of FIG. 2A.

FIG. 3A is a plan view illustrating a method of manufacturing a light receiving device.

FIG. 3B is a cross-sectional view taken along line A-A of FIG. 3A.

FIG. 4A is a plan view illustrating a method of manufacturing a light receiving device.

FIG. 4B is a cross-sectional view taken along line A-A of FIG. 4A.

FIG. 5A is a plan view illustrating a method of manufacturing a light receiving device.

FIG. 5B is a cross-sectional view taken along line A-A of FIG. 5A.

FIG. 6A is a plan view illustrating a method of manufacturing a light receiving device.

FIG. 6B is a cross-sectional view taken along line A-A of FIG. 6A.

FIG. 7A is a plan view illustrating a method of manufacturing a light receiving device.

FIG. 7B is a cross-sectional view taken along line A-A of FIG. 7A.

FIG. 8 is a plan view illustrating a light receiving device according to a comparative example.

FIG. 9 is a plan view illustrating a light receiving device according to a second embodiment.

FIG. 10A is a plan view illustrating a light receiving device according to a third embodiment.

FIG. 10B is a plan view illustrating a light receiving device according to a fourth embodiment.

### DETAILED DESCRIPTION

A light receiving device absorbs light and outputs an electrical signal. A reverse bias voltage is applied to the electrodes of the light receiving device. Concentration of an electric field on a part of the electrode may cause electrostatic-discharge breakdown (ESD breakdown).

Therefore, it is an object of the present disclosure to provide a light receiving device and a method of manufacturing the same capable of alleviating the concentration of an electric field.

### DESCRIPTION OF EMBODIMENTS OF PRESENT DISCLOSURE

First, the contents of embodiments of the present disclosure will be listed and explained.

(1) A light receiving device according to one aspect of the present disclosure includes a semiconductor layer, and at least one electrode provided on a surface of the semiconductor layer and electrically connected to the semiconductor layer. A plurality of mesas are formed from the semiconductor layer. The plurality of mesas are arranged in a two-dimensional array. The at least one electrode includes a plurality of electrodes, and each of the plurality of mesas is provided with a corresponding one of the plurality of electrodes. A contact portion has a periphery forming a closed curved shape, the contact portion being a portion at which the plurality of electrodes and the semiconductor layer are in contact with each other. Since the periphery of the contact portion has the closed curved shape, the concentration of an electric field can be alleviated. ESD breakdown can be suppressed.

(2) In the above (1), half or more of the periphery of the contact portion may be formed of a curved line. The concentration of the electric field can be effectively alleviated.

(3) In the above (1) or (2), a radius of curvature of the periphery of the contact portion may be 10 μm or more and may be half of a width of the contact portion or less. The concentration of the electric field can be effectively alleviated.

(4) In any one of the above (1) to (3), the light receiving device may further include an electrically insulating film covering the mesas. The electrically insulating film may have an opening above the mesas. The surface of the semiconductor layer may be exposed through the opening. The electrodes may be in contact with the surface exposed through the opening. A periphery of the opening may form the closed curved shape. By alleviating the concentration of the electric field, dielectric breakdown can be suppressed.

(5) In any one of the above (1) to (4), a shape of each of the mesas in plan view may include a curved line. A radius of curvature of the curved line of each of the mesas may be 5 μm or more. The concentration of the electric field can be effectively alleviated.

(6) In any one of the above (1) to (5), a width of each of the mesas may be larger than a width of the contact portion. A distance from the periphery of the contact portion to a periphery of each of the mesas may be 10 μm or less. The electric field applied to the mesas approaches uniformity.

(7) In any one of the above (1) to (6), each of the electrodes may include a metal layer and a bump. Each of the metal layers may be in contact with the surface of the semiconductor layer. Each of the bumps may be disposed on a surface of a corresponding one of the metal layers, the surface being opposite to another surface of the metal layer facing the semiconductor layer. The bumps may be used to connect the light receiving device to an external device.

(8) In the above (7), a distance from a periphery of each of the bumps to a periphery of a corresponding one of the mesas may be 5 μm or less. The electric field applied to mesas approaches uniformity.

(9) In any one of the above (1) to (8), the semiconductor layer may include a first semiconductor layer, a light receiving layer, a second semiconductor layer, and a third semiconductor layer sequentially stacked on top of one another. The first semiconductor layer may have a first conductivity-type. The second semiconductor layer and the third semiconductor layer each may have a second conductivity-type different from the first conductivity-type. The electrodes may be in contact with a surface of the third semiconductor layer at the contact portion. A pin junction can be formed. By applying a reverse bias voltage, a depletion layer is formed.

(10) A method of manufacturing a light receiving device includes forming a plurality of mesas on a semiconductor layer, and forming an electrode on the plurality of mesas, the electrode being electrically connected to the semiconductor layer. The plurality of mesas are arranged in a two-dimensional array. The electrode is provided on a surface of the semiconductor layer. A periphery of a contact portion forms a closed curved shape, the contact portion being a portion at which the electrode and the semiconductor layer are in contact with each other. Since the periphery of the contact portion has the closed curved shape, the concentration of the electric field can be alleviated. ESD breakdown can be suppressed.

### Details of Embodiments of Present Disclosure

Specific examples of light receiving devices and methods of manufacturing thereof according to embodiments of the present disclosure will be described below with reference to the drawings. The present disclosure is not limited to these examples, and is defined by the scope of the claims, and is intended to include all modifications within the meaning and scope equivalent to the scope of the claims.

### First Embodiment

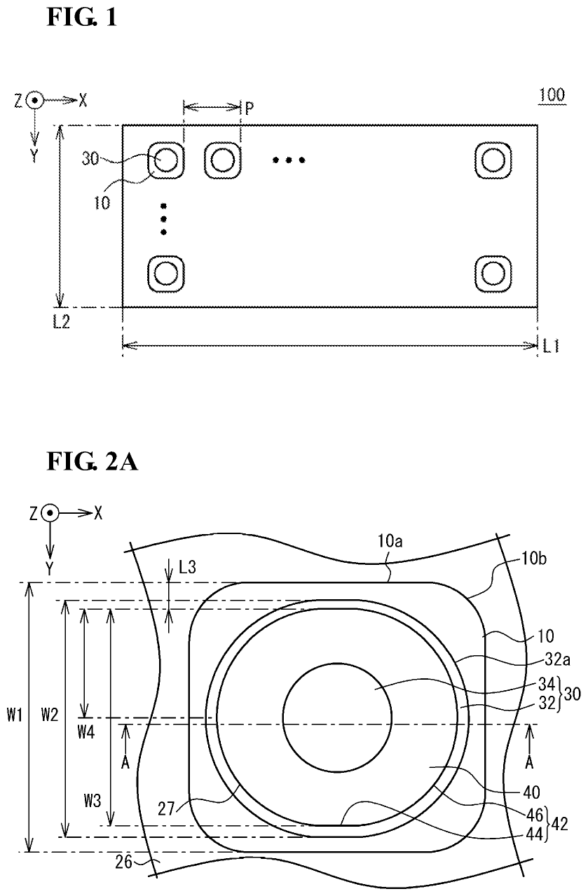

FIG. 1 is a plan view illustrating a light receiving device 100 according to a first embodiment. The shape of light receiving device 100 in plan view is a rectangle. Two sides of light receiving device 100 are parallel to the X-axis direction. The other two sides are parallel to the Y-axis direction. A top surface of light receiving device 100 is parallel to the XY plane. The Z-axis direction is a normal direction of the top surface of light receiving device 100. The X axis, the Y axis, and the Z axis are orthogonal to each other. A length L1 of light receiving device 100 in the X-axis direction is, for example, 10 mm. A length L2 in the Y-axis direction is, for example, 4.5 mm.

Light receiving device 100 is, for example, a focal plane array (FPA) sensor. A plurality of mesas 10 and electrodes 30 are arranged in a two-dimensional array on the top surface of light receiving device 100. A pitch P between two adjacent mesas 10 is, for example, 10 μm or more, and may be 30 μm, 50 μm, or 90 μm. Light receiving device 100 receives light such as near-infrared light and outputs an electric signal (current) corresponding to the intensity of the light.

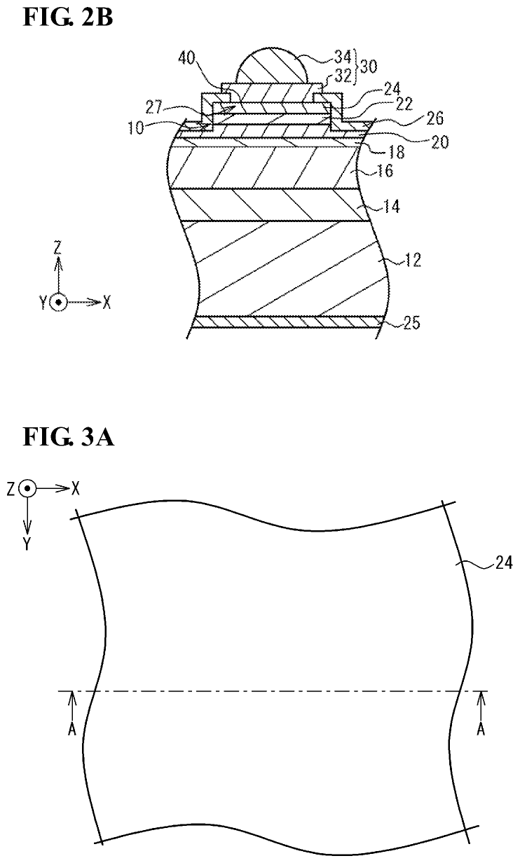

FIG. 2A is an enlarged plan view of mesa 10, showing one mesa 10. FIG. 2B is a cross-sectional view taken along line A-A of FIG. 2A.

As shown in FIG. 2B, light receiving device 100 includes a substrate 12, a semiconductor layer 14 (first semiconductor layer), a light receiving layer 16, a semiconductor layer 18, a semiconductor layer 20, a semiconductor layer 22 (second semiconductor layer), and a contact layer 24 (third semiconductor layer). On an upper surface of substrate 12, semiconductor layer 14, light receiving layer 16, semiconductor layer 18, and semiconductor layer 20 are sequentially stacked on top of one another. Semiconductor layer 20 has a protruding portion. Semiconductor layer 22 and contact layer 24 are provided on the protruding portion of semiconductor layer 20.

Semiconductor layer 20, semiconductor layer 22 contact layer 24 form mesa 10. Mesa 10 protrudes in the Z-axis direction from a portion of light receiving device 100 other than mesa 10. Semiconductor layer 20, semiconductor layer 18, light receiving layer 16 and semiconductor layer 14 extend under the plurality of mesas 10 and between mesas 10. An electrically insulating film 26 covers a portion of the upper surface and side surfaces of mesa 10 and the upper surface of semiconductor layer 20. Electrically insulating film 26 has an opening 27 above mesa 10.

Contact layer 24 is exposed through opening 27. A portion of the upper surface of contact layer 24 inside opening 27 is not covered with electrically insulating film 26.

Electrode 30 is provided on mesa 10 and electrically connected to contact layer 24. Electrode 30 includes a metal layer 32 and a bump 34. Bump 34 is disposed on the upper surface of metal layer 32. A peripheral portion of metal layer 32 rides on electrically insulating film 26, and a central portion of metal layer 32 is located inside opening 27 of electrically insulating film 26. Metal layer 32 is in contact with the upper surface of contact layer 24 through opening 27. A portion where metal layer 32 and contact layer 24 are in contact with each other is referred to as a contact portion 40.

Substrate 12 is formed of, for example, semi-insulating indium phosphide (InP) having a thickness of 0.5 mm. Substrate 12 is doped with iron (Fe), for example. Semiconductor layer 14 is formed of, for example, n-type (first conductivity-type) indium phosphide (n-InP) having a thickness of 2 μm. An n-type dopant is, for example, silicon (Si). Light receiving layer 16 is formed of, for example, indium gallium arsenide (InGaAs) having a thickness of 4 μm. Semiconductor layer 18 is formed of, for example, non-doped indium gallium arsenide phosphide (InGaAsP) having a thickness of 0.05 μm. Semiconductor layer 20 is formed of, for example, n-InP having a thickness of 0.5 μm. Semiconductor layer 22 is formed of, for example, p-type (second conductivity-type) indium phosphide (p-InP) having a thickness of 0.2 μm. Contact layer 24 is formed of, for example, p-type InGaAs having a thickness of 0.2 μm. A p-type dopant is, for example, zinc (Zn). Substrate 12 and the semiconductor layers may be formed of a compound semiconductor other than those described above.

An antireflection film 25 is provided on a surface (lower surface) of substrate 12 opposite to the surface on which semiconductor layer 14 is provided. Antireflection film 25 and electrically insulating film 26 are formed of insulators such as silicon nitride (SiN).

Metal layer 32 is formed of metal, and is, for example, a stacked body (Ti/Pt/Au) in which titanium, platinum, and gold are stacked in this order from the side closer to contact layer 24. Bump 34 is formed of metal such as indium (In).

Electrode 30 of FIG. 2B is connected to the p-type contact layer 24. Some electrodes (not shown) are connected to the n-type semiconductor layer 14. That is, light receiving device 100 has the p-type electrode and the n-type electrode. Bumps 34 are used to connect light receiving device 100 to an external device such as a readout circuit. A negative electric potential is applied to the p-type electrode and a positive electric potential is applied to the n-type electrode (reverse bias voltage).

The band gap of substrate 12 is larger than the energy of infrared light, for example. Infrared light is hardly absorbed by substrate 12, and is absorbed by light receiving layer 16. Light receiving layer 16 absorbs infrared light and generates carriers (electron-hole pairs). Carriers move and a current flows. Current is output from light receiving device 100 to an external device.

FIG. 2A shows mesa 10, electrode 30, and contact portion 40. Electrode 30 is located inside mesa 10. Bump 34 is located inside contact portion 40. A width W1 of mesa 10 is, for example, 100 μm or less, and may be 85 μm. A width W2 of metal layer 32 of electrode 30 is smaller than width W1 of mesa 10. A width W3 of opening 27 (the width of contact portion 40) is smaller than width W2 of metal layer 32, and is, for example, 80 μm. A shortest distance L3 from a periphery 42 of contact portion 40 to a periphery of mesa 10 is, for example, 10 μm or less and 5 μm or less, such as 2 μm, 2.5 μm.

The shape of bump 34 in plan view is circular. The shape of metal layer 32 in plan view and the shape of contact portion 40 in plan view are closed curved shapes, respectively. The closed curved shape has a curved line, such as an elliptical arc, and may include a straight line, but does not have a vertex.

The periphery of mesa 10 has a linear portion 10a and a curved portion 10b. Two of the four linear portions 10a are parallel to the X-axis direction. The other two are parallel to the Y-axis direction. Curved portion 10b is, for example, an arc, and is continuous with two linear portions 10a. A radius of curvature of curved portion 10b is, for example, 10 μm or more, and may be 20 μm or more, or 30 μm or more.

The edge of opening 27 of electrically insulating film 26 becomes periphery 42 of contact portion 40. Periphery 42 forms a closed curved shape. Periphery 42 has two linear portions 44 and two curved portions 46. Linear portion 44 is parallel to the X-axis direction. Curved portion 46 is continuous with two linear portions 44 and is convex outward from contact portion 40. Curved portion 46 is an elliptical arc, a circular arc, or the like. Curved portion 46 is longer than linear portion 44. Two curved portions 46 occupy, for example, half or more of the length of periphery 42. A radius of curvature of curved portion 46 is, for example, 10 μm or more, may be 20 μm or more, 30 μm or more, and is half (W4) or less of width (equal to the width of contact portion 40) W3 of opening 27. That is, the radius of curvature of curved portion 46 may be at most W4.

A periphery of metal layer 32 of electrode 30 forms a closed curved shape similar to periphery 42 of contact portion 40, and has, for example, the shape obtained by enlarging periphery 42 by a constant multiple. Metal layer 32 has a curved portion 32a. Curved portion 32a is an elliptical arc, a circular arc, or the like. A radius of curvature of curved portion 32a is, for example, greater than a radius of curvature R1 of curved portion 46 by 1

(Method of Manufacturing)

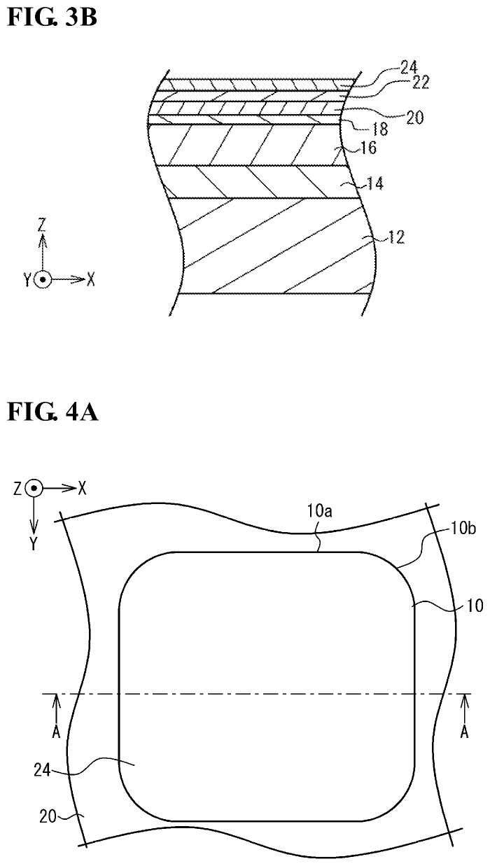

FIGS. 3A, 4A, 5A, 6A and 7A are plan views each showing a method of manufacturing of light receiving device 100, illustrating a portion corresponding to one mesa 10. FIGS. 3B, 4B, 5B, 6B and 7B are cross-sectional views taken along line A-A of the corresponding plan views.

Semiconductor layer 14, light receiving layer 16, semiconductor layers 18, 20 and 22, and contact layer 24 are epitaxially grown in this order on one surface of substrate 12 by metal organic chemical vapor deposition (MOCVD) method or the like. As shown in FIGS. 3A and 3B, contact layer 24 becomes a top surface.

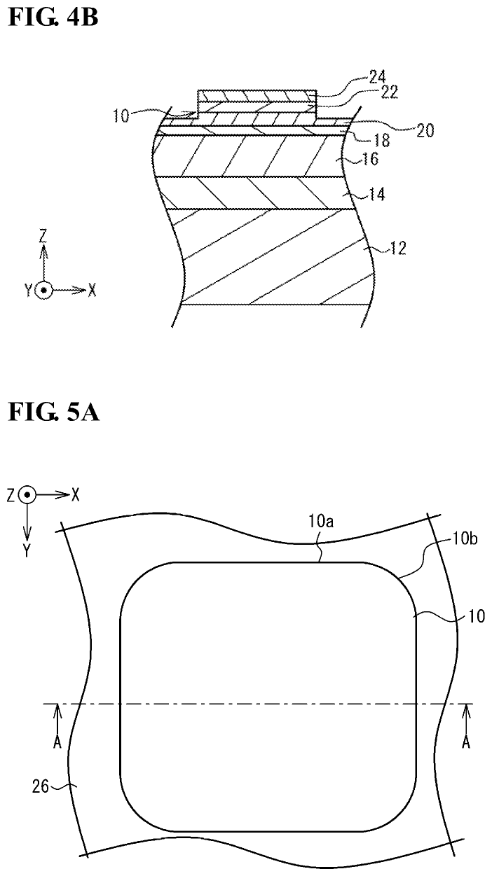

As shown in FIGS. 4A and 4B, mesa 10 is formed. A mask (not shown) is provided on contact layer 24. The shape of mesa 10 in plan view can be adjusted by the shape of the mask. A portion exposed from the mask is etched. The etching proceeds halfway through semiconductor layer 20. The etching is dry etching or wet etching. After etching, the mask is removed.

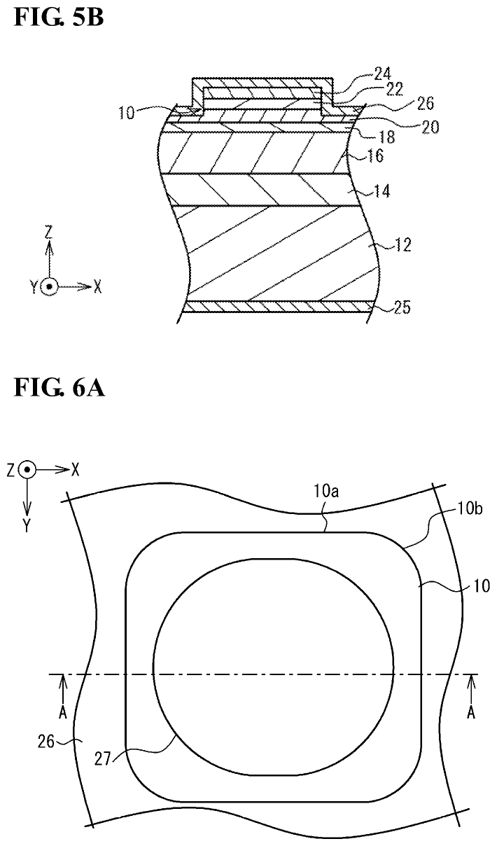

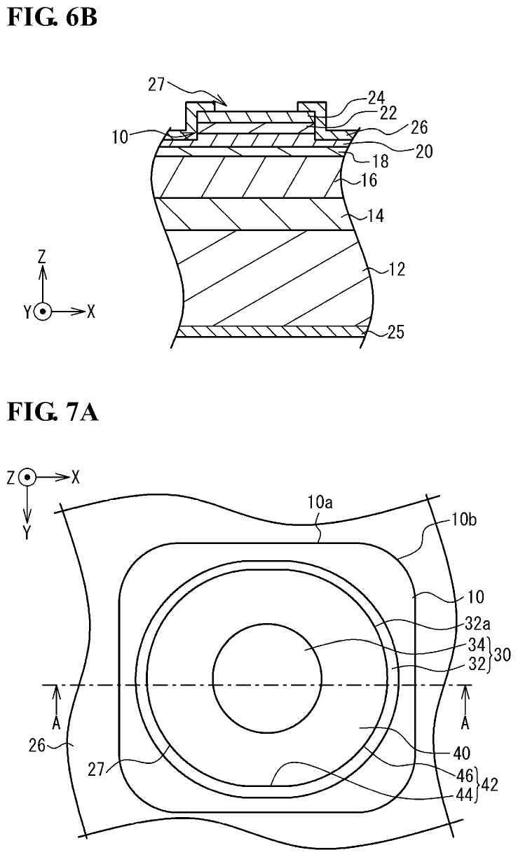

As shown in FIGS. 5A and 5B, electrically insulating film 26 is formed by, for example, plasma enhanced chemical vapor deposition (PECVD) method. Electrically insulating film 26 covers the side surfaces and the upper surface of mesa 10. Antireflection film 25 is deposited on the lower surface of substrate 12. As shown in FIGS. 6A and 6B, opening 27 is formed in a portion of electrically insulating film 26 above mesa 10 by etching. A mask (not shown) is provided on electrically insulating film 26. A portion of electrically insulating film 26 exposed from the mask is removed by etching. The shape of opening 27 is determined by the shape of the mask. After etching, the mask is removed.

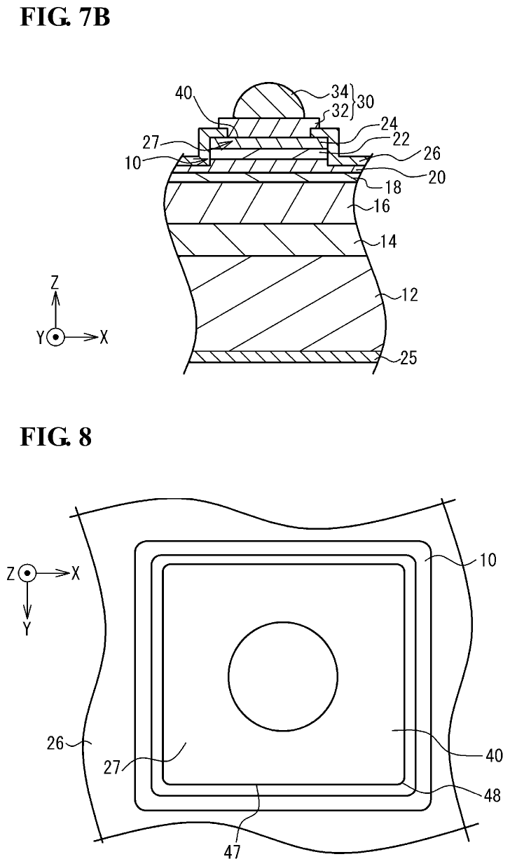

As shown in FIGS. 7A and 7B, metal layer 32 is formed on mesa 10 by, for example, vacuum deposition and lift-off. Metal layer 32 is in contact with contact layer 24 exposed through opening 27. Bump 34 is formed on metal layer 32 by a reflow process. Through the above steps, light receiving device 100 is manufactured.

### Comparative Example

FIG. 8 is a plan view illustrating a light receiving device according to a comparative example, showing one mesa 10. The shapes of mesa 10, metal layer 32 of electrode 30, and contact portion 40 in plan view are rectangular. The vertex of the rectangle may be a pointed shape or a curved line shape. In the example of FIG. 8, the vertex is a curved line. A radius of curvature of the vertex of mesa 10 is, for example, 1 μm. Contact portion 40 has four linear portions 47 and four vertices 48. A radius of curvature of vertex 48 of contact portion 40 is, for example, 5 μm. The angle of vertex 48 is 90°. When a reverse bias voltage is applied, an electric field tends to concentrate on vertex 48. Due to the concentration of the electric field, ESD breakdown may occur in the vicinity of vertex 48. Electrically insulating film 26 may be dielectrically broken down and melt.

According to the first embodiment, at contact portion 40, metal layer 32 of electrode 30 is in contact with contact layer 24. When a reverse bias voltage is applied to light receiving device 100, an electric field is applied beneath contact portion 40. As shown in FIG. 2A, periphery 42 of contact portion 40 of the first embodiment is a closed curved shape and has no vertex. Since the concentration of the electric field in contact portion 40 is alleviated, ESD breakdown can be suppressed.

As shown in FIG. 2A, periphery 42 of contact portion 40 has two linear portions 44 and two curved portions 46. Curved portion 46 is, for example, an elliptical arc or a circular arc. An electric field is unlikely to be concentrated in curved portion 46. Since periphery 42 has curved portion 46, the electric field concentration can be effectively alleviated and ESD breakdown can be suppressed. Half or more of periphery 42 is curved portions 46. The electric field concentration can be effectively alleviated. The ratio of length of periphery 42 occupied by curved portions 46 may be 30% or more, 40% or more, 50% or more, 60% or more, 80% or more, or 90% or more. Periphery 42 may have three or more curved portions 46. The whole of periphery 42 may be curved portion 46.

The radius of curvature R1 of curved portion 46 of periphery 42 is equal to or less than the length of W4 which is half of width W3 of opening 27. By setting the radius of curvature R1 to be equal to W4, curved portion 46 can be made longer. The electric field concentration can be effectively alleviated. The radius of curvature R1 may be 50%, 40% or more, 30% or more, or 10% or more of width W3. The radius of curvature R1 may be 10 μm or more, 20 μm or more, 30 μm or more, etc.

The shape of metal layer 32 of electrode 30 in plan view is a closed curved shape such as an enlarged shape of contact portion 40. The electric field concentration can be effectively alleviated. An radius of curvature R2 of curved portion 32a of metal layer 32 may be greater than, equal to, or less than the radius of curvature R1 of contact portion 40.

As shown in FIG. 2B, semiconductor layers 20 and 22, and contact layer 24 form mesa 10. Electrically insulating film 26 covers mesa 10. Electrically insulating film 26 has opening 27 above mesa 10. Electrode 30 is in contact with contact layer 24 exposed through opening 27. That is, as shown in FIG. 2A, contact portion 40 is formed inside opening 27. The edge of opening 27 becomes periphery 42 of contact portion 40. The shape of periphery 42 can be determined by the shape of the etching mask provided on electrically insulating film 26, and can be a closed curved shape as shown in FIG. 2A. By alleviating the concentration of an electric field, dielectric breakdown can be suppressed.

The shape of mesa 10 in plan view includes linear portion 10a and curved portion 10b. Since mesa 10 includes curved portion 10b, an electric field concentration can be effectively suppressed. An radius of curvature R3 of curved portion 10b may be, the same as the radius of curvature R1 of curved portion 46 of periphery 42, less than R1, or greater than R1. The radius of curvature R3 of curved portion 10b may be 10% or more, 30% or more, 40% or more, 50%, etc. of width W1 of mesa 10. The radius of curvature R3 may be 5 μm or more, 10 μm or more, 20 μm or more, 30 μm or more. The ratio of curved portions 10b in the circumference of mesa 10 may be 20% or more, 30% or more, 40% or more, 50% or more, 60% or more, or the like. Mesa 10 may have, for example, an enlarged shape of contact portion 40.

Width W1 of mesa 10 is larger than width W2 of metal layer 32 and width W3 of contact portion 40. Shortest distance L3 from periphery 42 of contact portion 40 to the periphery of mesa 10 is, for example, 10 μm or less. An electric field is applied under contact portion 40, and a depletion layer is easily formed. By bringing periphery 42 of contact portion 40 close to the periphery of mesa 10, the electric field is applied to a wide area of mesa 10. Light receiving sensitivity of light receiving device 100 is improved. Distance L3 may be 15 μm or less, 10 μm or less, 5 μm or less, 3 μm or less, or the like.

Electrode 30 has bump 34. By using bump 34, light receiving device 100 can be electrically connected to an external device for application of voltage, output of current, or the like. As shown in FIG. 1, the plurality of mesas 10 are arranged in a two-dimensional array. Light receiving device 100 is the FPA having a plurality of pixels. Pitch P between mesas 10 are, for example, several tens of Mesas 10 are separated from each other, and it is preferable that mesas 10 are enlarged. For example, width W1 of mesa 10 is smaller than pitch P by several By enlarging mesas 10, the area that can receive light is enlarged. The light receiving sensitivity of light receiving device 100 is improved. The concentration of the electric field in each of the plurality of mesas 10 can be alleviated, and ESD breakdown can be suppressed.

Light receiving device 100 includes semiconductor layer 14, light receiving layer 16, semiconductor layers 18, 20, and 22, and contact layer 24. The n-type semiconductor layer 14, light receiving layer 16, the p-type semiconductor layer 22 and contact layer 24 form a pin junction. When a reverse bias voltage is applied to light receiving device 100, a depletion layer is formed. Light receiving layer 16 absorbs light and generates carriers. Carriers move and a current flows. That is, light receiving device 100 detects light and outputs a current. At contact portion 40, electrode 30 is in contact with contact layer 24. Since the electric field concentration is suppressed, ESD breakdown can be suppressed. The stacking order of the p-type semiconductor layer and the n-type semiconductor layer may be reversed from the example of FIG. 2B.

### Second Embodiment

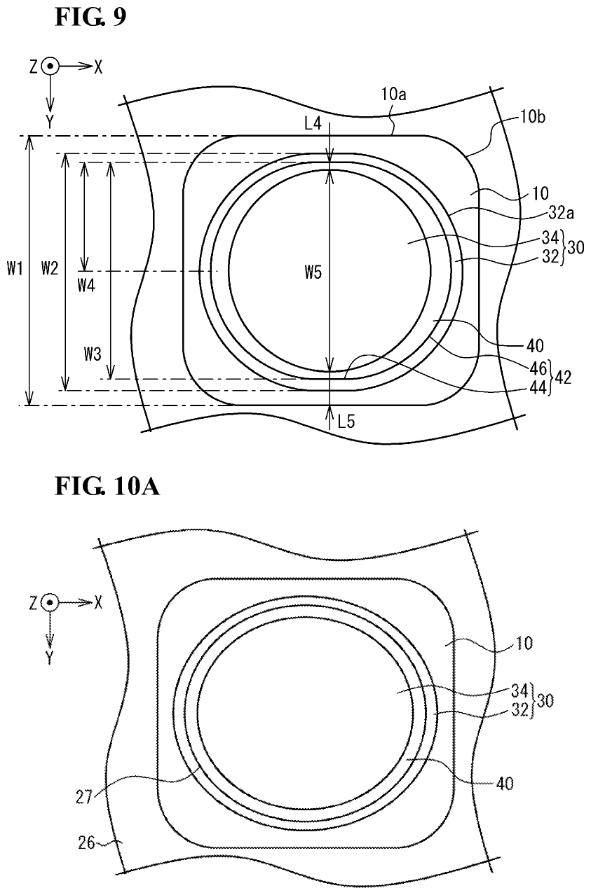

FIG. 9 is a plan view illustrating a light receiving device according to a second embodiment, showing one mesa 10. Descriptions for the same configurations as those of the first embodiment will be omitted.

As shown in FIG. 9, bump 34 of electrode 30 is located inside contact portion 40. The shape of bump 34 in plan view is a closed curved shape such as a circular shape. A width W5 (diameter) of bump 34 is a few μm smaller than width W3 of contact portion 40. A shortest distance L4 from the edge of bump 34 to periphery 42 of contact portion 40 is, for example, 5 μm or less, and may be 3 μm or less, 2 μm or less, or 1 μm or less. A distance L5 from the edge of bump 34 to the edge of mesa 10 may be 10 μm or less, or may be 5 μm or less.

According to the second embodiment, bump 34 has a closed curved shape similar to contact portion 40. The electric field concentration can be effectively alleviated. When a reverse bias voltage is applied, an electric field is transiently generated under bump 34. Since bump 34 is larger than bump 34 of the first embodiment, the electric field applied to mesa 10 can be made more uniform. Since the electric field spreads over the whole of mesa 10, the concentration of the electric field can be suppressed and ESD breakdown can be suppressed.

Shortest distance L4 from a periphery of bump 34 to periphery 42 of contact portion 40 may be, for example, 5 μm or less, 10 μm or less, 3 μm or less. Distance L5 from the edge of bump 34 to the edge of mesa 10 may be 10 μm or less, 5 μm or less, or 4 μm or less. As distances L4 and L5 decrease, the ratio of the area occupied by bump 34 to the area of the upper surface of mesa 10 increases. The electric field applied to mesa 10 can be made nearly uniform.

Table 1 shows examples of dimensions. In any of No. 1 to No. 3 of Table 1, the shapes of periphery 42 of contact portion 40 and metal layer 32 in plan view are closed curved shapes as shown in FIG. 9. The shape of bump 34 in plan view is circular.

TABLE 1

| | | | | RADIUS | RADIUS | |
|---|---|---|---|---|---|---|
| | | | | OF | OF | |
| | | | | CURV- | CURV- | |
| | | | WIDTH | ATURE | ATURE | WIDTH |
| | | WIDTH | W3 OF | R1 OF | R2 OF | W5 |
| | | W1 OF | CONTACT | CURVED | CURVED | OF |
| | | MESA | PORTION | PORTION | PORTION | BUMP |
| | PITCH P | 10 | 40 | 46 | 32a | 34 |
| | [μm] | [μm] | [μm] | [μm] | [μm] | [μm] |
| No. 1 | 90 | 85 | 80 | 40 | 41 | 78 |
| No. 2 | 50 | 47 | 42 | 21 | 22 | 40 |
| No. 3 | 30 | 27 | 23 | 11 | 12 | 21 |

In No. 1 of Table 1, pitch P of mesa 10 is 90 and width W1 of mesa 10 is 85 μm. Width W3 of contact portion 40 is 80 μm. The radius of curvature R1 of curved portion 46 of contact portion 40 is at most 40 μm. The radius of curvature R2 of curved portion 32a of metal layer 32 is 41 μm. Diameter W5 of bump 34 is 78 μm.

In No. 2 of Table 1, pitch P of mesa 10 is 50 and width W1 of mesa 10 is 47 μm. Width W3 of contact portion 40 is 42 The radius of curvature R1 of curved portion 46 is at most 21 μm. The radius of curvature R2 of curved portion 32a is 22 Diameter W5 of bump 34 is 40 μm.

In No. 3 of Table 1, pitch P of mesa 10 is 30 and width W1 of mesa 10 is 27 μm. Width W3 of contact portion 40 is 23 μm. The radius of curvature R1 of curved portion 46 is at most 11 μm. The radius of curvature R2 of curved portion 32a is 12 μm. Diameter W5 of bump 34 is 21 μm.

### Third Embodiment

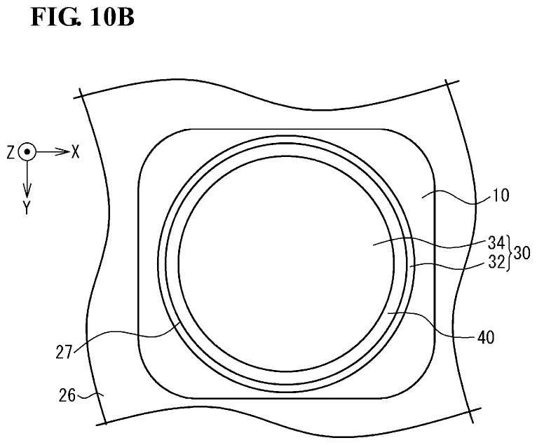

FIG. 10A is a plan view illustrating a light receiving device according to a third embodiment, showing one mesa 10. Descriptions of the same configurations as those of the first embodiment or the second embodiment will be omitted. The shapes of metal layer 32 and bump 34 of electrode 30, and contact portion 40 in plan view are all elliptical. The center of metal layer 32, the center of bump 34, and the center of contact portion 40 are the same.

### Fourth Embodiment

FIG. 10B is a plan view illustrating a light receiving device according to a fourth embodiment, showing one mesa 10. Descriptions of the same configurations as those of the first embodiment or the second embodiment will be omitted. The shapes of metal layer 32 and bump 34 of electrode 30, and contact portion 40 in plan view are all circles. The center of metal layer 32, the center of bump 34, and the center of contact portion 40 are the same.

According to the third and fourth embodiments, the shapes of contact portion 40, metal layer 32, and bump 34 are elliptical or circular, respectively, and each does not have a straight line or a vertex. Since the concentration of an electric field can be effectively reduced, ESD breakdown can be suppressed.

Although the embodiments of the present disclosure have been described in detail above, the present disclosure is not limited to the specific embodiments, and various modifications and changes can be made within the scope of the gist of the present disclosure described in the claims.

What is claimed is:

1. Alight receiving device comprising:
a semiconductor layer; and
at least one electrode provided on a surface of the semiconductor layer and electrically connected to the semiconductor layer,
wherein a plurality of mesas are formed from the semiconductor layer,
wherein the plurality of mesas are arranged in a two-dimensional array,
wherein the at least one electrode includes a plurality of electrodes, and each of the plurality of mesas is provided with a corresponding one of the plurality of electrodes, and
wherein a contact portion has a periphery forming a closed curved shape, the contact portion being a portion at which the plurality of electrodes and the semiconductor layer are in contact with each other.

2. The light receiving device according to claim 1,
wherein half or more of the periphery of the contact portion is formed of a curved line.

3. The light receiving device according to claim 1
wherein a radius of curvature of the periphery of the contact portion is 10 μm or more and is half of a width of the contact portion or less.

4. The light receiving device according to claim 1, further comprising:
an electrically insulating film covering the mesas,
wherein the electrically insulating film has an opening above the mesas,
wherein the surface of the semiconductor layer is exposed through the opening,
wherein the electrodes are in contact with the surface exposed through the opening, and
wherein a periphery of the opening forms the closed curved shape.

5. The light receiving device according to claim 1,
wherein a shape of each of the mesas in plan view includes a curved line, and
wherein a radius of curvature of the curved line of each of the mesas is 5 μm or more.

6. The light receiving device according to claim 1,
wherein a width of each of the mesas is larger than a width of the contact portion, and
wherein a distance from the periphery of the contact portion to a periphery of each of the mesas is 10 μm or less.

7. The light receiving device according to claim 1,
wherein each of the electrodes includes a metal layer and a bump,
wherein each of the metal layers is in contact with the surface of the semiconductor layer, and
wherein each of the bumps is disposed on a surface of a corresponding one of the metal layers, the surface being opposite to another surface of the metal layer facing the semiconductor layer.

8. The light receiving device according to claim 7,
wherein a distance from a periphery of each of the bumps to a periphery of a corresponding one of the mesas is 5 μm or less.

9. The light receiving device according to claim 1,
wherein the semiconductor layer includes a first semiconductor layer, a light receiving layer, a second semiconductor layer, and a third semiconductor layer sequentially stacked on top of one another,
wherein the first semiconductor layer has a first conductivity-type,
wherein the second semiconductor layer and the third semiconductor layer each have a second conductivity-type different from the first conductivity-type, and
wherein the electrodes are in contact with a surface of the third semiconductor layer at the contact portion.

10. A method of manufacturing a light receiving device, the method comprising:
forming a plurality of mesas on a semiconductor layer; and
forming an electrode on the plurality of mesas, the electrode being electrically connected to the semiconductor layer,
wherein the plurality of mesas are arranged in a two-dimensional array,
wherein the electrode is provided on a surface of the semiconductor layer, and
wherein a periphery of a contact portion forms a closed curved shape, the contact portion being a portion at which the electrode and the semiconductor layer are in contact with each other.
